(19) United States
(12) Patent Application Publication
(10) Pub. No.: US 2025/0113414 A1
(43) Pub. Date: Apr. 3, 2025

(54) SYSTEMS AND METHODS FOR MEASURING INDUCTION COIL PARAMETERS

(71) Applicant: Haier US Appliance Solutions, Inc., Wilmington, DE (US)

(72) Inventors: Ali Faraji-Tajrishi, Louisville, KY (US); Nathaniel Lehrer, Louisville, KY (US)

(21) Appl. No.: 18/478,573

(22) Filed: Sep. 29, 2023

(51) Int. Cl. H05B 6/06; G01R 25/00; H05B 6/04

(52) U.S. Cl. CPC H05B 6/062; G01R 25/005; H05B 6/04

(57) ABSTRACT

An induction heating system is provided. The induction heating system includes an induction heating element operable to inductively heat a load with a magnetic field. The induction heating system further includes a power supply circuit coupled to an alternating current (AC) power supply configured to supply a power signal to the induction heating system. The power supply circuit includes an inverter. The induction heating system further includes a conditioning circuit configured to output a derived voltage signal based at least in part on a voltage across a resonant capacitor of the induction heating system. The induction heating system further includes a controller operably coupled to the conditioning circuit and the power supply circuit. The controller is configured to determine one or more operating parameters of the induction heating system based at least in part on the derived voltage signal generated by the conditioning circuit.

### FIELD

Example aspects of the present disclosure generally relate to induction heating systems used in cooktop appliances and, more particularly, to monitoring induction coil phase and current in induction heating systems and apparatuses.

### BACKGROUND

Induction cooking appliances are more efficient, have greater temperature control precision and provide more uniform cooking than other conventional cooking appliances. In conventional cooktop systems, an electric or gas heat source is used to heat cookware in contact with the heat source. This type of cooking is inefficient because only the portion of the cookware in contact with the heat source is directly heated. The rest of the cookware is heated through conduction that causes non-uniform cooking throughout the cookware. Heating through conduction takes an extended period of time to reach a desired temperature.

In contrast, induction cooking systems use electromagnetism which turns cookware of the appropriate material into a heat source. Such appropriate materials may include ferromagnetic materials in order to effectively capture the magnetic field produced by the induction cooking coil. Other materials, such as aluminum, will be very inefficient for cooking on an induction cooking system. A power supply provides a signal having a frequency to the induction coil. When the coil is activated, a magnetic field is produced which induces a current on the bottom surface of the cookware. The induced current on the bottom surface then induces even smaller currents (Eddy currents) within the cookware thereby providing heat throughout the cookware.

### SUMMARY

Aspects and advantages of embodiments of the present disclosure will be set forth in part in the following description, or can be learned from the description, or can be learned through practice of the embodiments.

One example aspect of the present disclosure is directed to an appliance. The appliance may include a cooktop, a user interface having a user input, and an induction heating system. The induction heating system may include an induction heating element operable to inductively heat a load with a magnetic field. The induction heating system may further include a power supply circuit coupled to an alternating current (AC) power supply that is configured to supply a power signal to the induction heating system. The power supply circuit may include an inverter. The induction heating system may further include a conditioning circuit configured to output a derived voltage signal based at least in part on a voltage across a resonant capacitor of the induction heating system. The induction heating system may further include a controller operably coupled to the conditioning circuit and the power supply circuit. The controller may be configured to determine one or more operating parameters of the induction heating system based at least in part on the derived voltage signal generated by the conditioning circuit.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a perspective view of an example induction cooktop appliance according to example embodiments of the present disclosure;

FIG. 2A depicts a block diagram of an example induction heating system according to example embodiments of the present disclosure;

FIG. 2B depicts a circuit schematic of the example induction heating system of FIG. 2A according to example embodiments of the present disclosure;

FIG. 3 depicts a flow diagram of an example method for operating an appliance according to example embodiments of the present disclosure;

FIG. 4 depicts an example conditioning circuit of the example induction heating system of FIGS. 2A-2B according to example embodiments of the present disclosure;

FIG. 5 depicts an example phase detection circuit of the example induction heating system of FIGS. 2A-2B according to example embodiments of the present disclosure;

FIG. 6 depicts an example phase detection circuit of the example induction heating system of FIGS. 2A-2B according to example embodiments of the present disclosure;

FIG. 7 depicts an example phase detection circuit of the example induction heating system of FIGS. 2A-2B according to example embodiments of the present disclosure; and

FIG. 8 depicts an example phase detection circuit of the example induction heating system of FIGS. 2A-2B according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure relate to induction cooktop appliances. In particular, example aspects of the present disclosure provide an induction cooktop appliance having an induction heating element (e.g., induction coil) operable to inductively heat a load with a magnetic field. The induction cooktop appliance may further include a power supply circuit coupled to an alternating current (AC) power supply configured to provide a power signal to the induction heating element. Conventional induction cooktop appliances are typically powered by standard 40 A (Amperes), 240 VAC (Volts Alternating Current) power supplies. In contrast, other conventional cooktop appliances (e.g., gas-powered cooktops) are typically powered by standard 15 A, 120 VAC power supplies.

Induction heating systems having heating elements, such as an induction coil, have a variety of operating parameters that can be used to determine a variety of operational characteristics/states. For instance, one operating parameter is the amount of current supplied to the coil from the power supply circuit (e.g., peak current through the induction coil). Another example of an operating parameter is the phase difference between the coil current and the voltage across the resonant tank of the induction heating system. These operating parameters are key in deciding a variety of operational characteristics/states of the induction heating system, such as whether a load (e.g., cookware, pan, etc.) is present on the coil and/or calculating the total power output of the induction coil. Thus, systems and methods for measuring these operating parameters are an important part of appliances that include an induction heating system, such as induction cooktop appliances.

Traditional induction heating systems require expensive, non-ideal systems and methods to measure these operating parameters. For instance, conventional induction heating systems typically use various current sensing devices (e.g., current transducers, current sensors, current transformers, Hall effect sensors, etc.) to measure the coil current and/or rely on complex arithmetic involving quickly sampled analog-to-digital (A/D) data. Additionally, passive components, such as shunt resistors, may also be used to measure the coil current. These conventional systems and methods, however, require expensive components that provide signals with a variety of signal infirmities, such as noise. As a result, in designing traditional induction heating systems, many design compromises must be made in order to monitor and measure the associated operating parameters. Thus, an induction heating system having systems and methods that accurately measure and monitor the operating parameters without the drawbacks discussed above is desired.

Accordingly, example aspects of the present disclosure provide systems and methods for measuring one or more operating parameters of an induction heating system. In particular, example aspects of the present disclosure provide an induction heating system operable to measure coil current and the phase difference between the voltage across the resonant tank and the coil current using only the voltage across the resonant capacitor. An induction heating system according to the present disclosure may also use a current sensing device to improve the measurement of the coil current.

The induction heating system may include an induction heating element, such as an induction coil, operable to inductively heat a load, such as a pot or pan, with a magnetic field. The induction heating system may also include a power supply circuit coupled to an AC power supply configured to supply a power signal to the induction heating system. More particularly, the AC power supply may provide the power signal to an inverter of the power supply circuit.

The induction heating system may include a one or more resonant capacitors. As will be discussed in greater detail below, the voltage across the resonant capacitor may be used to determine the current through the induction coil. This is due to the relationship between the current (I), the capacitance (C), and the rate of change in the voltage across the capacitor with respect to time

$$( \frac{dv}{dt} ) ,$$

which is reflected by the following formula:

$$I = C * \frac{dv}{dt}$$

Furthermore, the coil current (I_{L}) is also expected to be approximately two times the individual resonant capacitor current (I_{C}). As used herein, “approximately” or “about” includes values within ten percent (10%) of the nominal value.

Accordingly, example aspects of the present disclosure provide for an induction heating system having a conditioning circuit configured to output a derived voltage signal based at least in part on a voltage across a resonant capacitor of the induction heating system. More particularly, by using a resistor divider, taking a derivative of the voltage across the resonant capacitor, and adding a direct-current (DC) offset, the conditioning circuit may recreate the coil current as a low voltage signal (hereinafter “derived voltage signal”). A “low voltage” signal is a signal having a voltage of about 20 volts or less. Thus, a conditioning circuit according to the present disclosure may include a resistor divider configured to receive a signal indicative of the voltage across the resonant capacitor, a differentiator circuit coupled to the resistor divider that is configured to determine a derivative of a signal output by the resistor divider, and an offset circuit coupled to the differentiator circuit that is configured to add a direct-current (DC) offset to a signal output by the differentiator circuit.

The induction heating system may further include a controller operably coupled to the conditioning circuit and to the power supply circuit. The controller may include one or more processors and may be configured to determine one or more operating parameters of the induction heating system based at least in part on the derived voltage signal generated by the conditioning circuit.

Furthermore, example aspects of the present disclosure also provide for an induction heating system having a phase detection circuit coupled to the conditioning circuit and to the controller. The phase detection circuit may be configured to output a voltage signal representative of a phase of the coil current based at least in part on the derived voltage signal output by the conditioning circuit.

As will be discussed in greater detail below, the derived voltage signal may be fed to the controller to help calculate the coil current and the power of the inverter. The derived voltage signal may also be used to detect the phase of the coil current. For instance, in some embodiments, the derived voltage signal may pass through a comparator to create a positive pulse when the derived voltage signal is less than a reference voltage equal to the DC offset added by the offset circuit of the conditioning circuit. Next, the signal output from the comparator would be compared to the pulse-width modulated (PWM) signal fed to a switching device (e.g., high-side switch) of the induction heating system. This PWM signal is a close representation of the voltage across the resonant tank of the induction heating system. The resulting signal may then be a pulse that may be sent through a filter (e.g., low-pass filter (LPF)), then to the controller. Alternatively, the resulting signal may then be sent directly to the controller. Following receipt of that signal, the controller may calculate the phase of the coil current.

Additionally, in some embodiments, the induction heating system may further include a shunt resistor operable to measure the current. More particularly, a shunt resistor may be used to measure the current, which may output a current feedback signal representative of the peak current provided to the induction coil. The resulting current feedback signal may be conditioned (e.g., filtered, amplified, offset, etc.) before ultimately being sent to the controller. Using these two points of measurement may help reduce the design tradeoffs associated with the tolerance of the resonant capacitors and conditioning circuit. It should be understood that any suitable current sensing device (e.g., current transformer, Hall effect sensor, etc.) may be used without deviating from the scope of the present disclosure.

Additionally, in some embodiments, both the derived voltage signal and the current feedback signal may be fed to the controller. More particularly, the peak current measured by the shunt resistor may represent the peak coil current multiplied by a fixed scalar (e.g., the shunt current is expected to be approximately half of the coil current). Thus, the current feedback signal may be used to adjust the measured values of the derived voltage signal to compensate for the tolerance of the resonant capacitor.

In other embodiments, the derived voltage signal may be fed directly to the controller. The controller may use the derived voltage signal to calculate the coil current and the total power output of the inverter using circuitry internal to the controller itself. More particularly, internally to the controller, the derived voltage signal may start a time when a PWM signal fed back to the controller is positive. The controller may stop the timer when the derived voltage signal is greater than the offset reference voltage representative of the DC offset added by the offset circuit of the conditioning circuit. The resulting time may then be used, along with the operating frequency, to calculate the phase of the coil current.

Example aspects of the present disclosure provide numerous technical effects and benefits. For instance, an induction heating system according to the present disclosure may provide a lower-cost design as opposed to conventional direct-measurement methods, such as current transducers. Furthermore, example aspects of the present disclosure provide improvements over measuring the phase difference between the coil current and the voltage with an isolated shunt resistor. Even further, the resulting data measured and output by the various components of the induction heating system may be cleaner and more reliable. Example aspects of the present disclosure also provide an induction heating system that does not rely on complex arithmetic of quickly sampled A/D data, which reduces the needs for costly design compromises. Even further, example systems and methods provided by the present disclosure may use a shunt resistor, alone, to determine the coil current and to determine the phase difference between the voltage across the resonant tank and the coil current. These measurements may be adjusted to compensate for the tolerance associated with the resonant tank, thereby improving the accuracy and reliability of the operation parameter determination, such as the determination of whether a pan is present on top of the induction coil and the determination of how much power is being transferred to the pan, if present.

As used herein, the terms “first,” “second,” and “third” may be used interchangeably to distinguish one component from another and are not intended to signify location or importance of the individual components. The terms “includes” and “including” are intended to be inclusive in a manner similar to the term “comprising.” Similarly, the term “or” is generally intended to be inclusive (e.g., “A or B” is intended to mean “A or B or both”). The term “at least one of” in the context of, e.g., “at least one of A, B, and C” refers to only A, only B, only C, or any combination of A, B, and C. In addition, here and throughout the specification and claims, range limitations may be combined and/or interchanged. Such ranges are identified and include all the sub-ranges contained therein unless context or language indicates otherwise. For example, all ranges disclosed herein are inclusive of the endpoints, and the endpoints are independently combinable with each other. The singular forms “a,” “an,” and “the” include plural references unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “generally,” “about,” “approximately,” and “substantially,” are not to be limited to the precise value specified. In at least some instances, the approximating language may correspond to the precision of an instrument for measuring the value, or the precision of the methods or machines for constructing or manufacturing the components and/or systems. For example, the approximating language may refer to being within a 10 percent margin, i.e., including values within ten percent greater or less than the stated value. In this regard, for example, when used in the context of an angle or direction, such terms include within ten degrees greater or less than the stated angle or direction, e.g., “generally vertical” includes forming an angle of up to ten degrees in any direction, e.g., clockwise or counterclockwise, with the vertical direction V.

The word “exemplary” is used herein to mean “serving as an example, instance, or illustration.” In addition, references to “an embodiment” or “one embodiment” does not necessarily refer to the same embodiment, although it may. Any implementation described herein as “exemplary” or “an embodiment” is not necessarily to be construed as preferred or advantageous over other implementations. Moreover, each example is provided by way of explanation of the invention, not limitation of the invention. In fact, it will be apparent to those skilled in the art that various modifications and variations can be made in the present invention without departing from the scope of the invention. For instance, features illustrated or described as part of one embodiment can be used with another embodiment to yield a still further embodiment. Thus, it is intended that the present invention covers such modifications and variations as come within the scope of the appended claims and their equivalents.

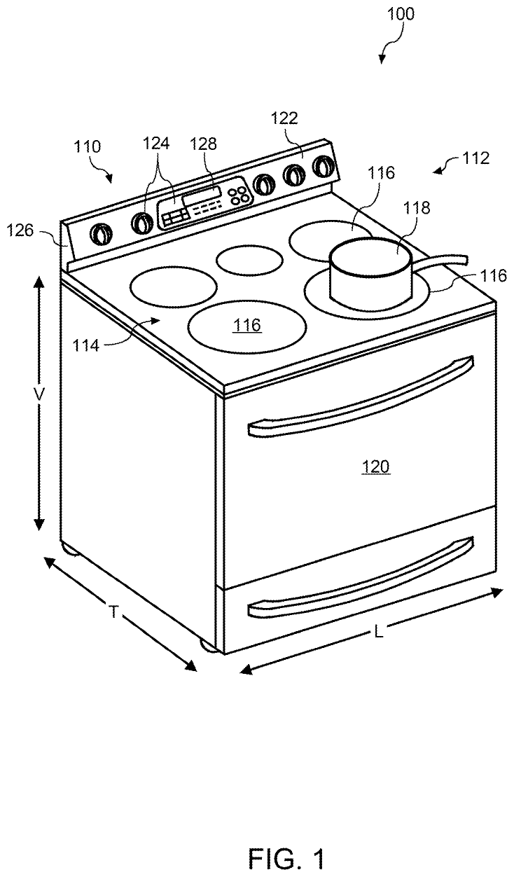

FIG. 1 depicts a perspective view of an induction cooktop appliance 100. The induction cooktop appliance includes a range 110. The range 110 includes a cooktop 112, such as an induction cooktop. Range 110 is provided by way of example only and is not intended to limit the present subject matter to the arrangement shown in FIG. 1. Thus, the present subject matter may be used with other range 110 and/or cooktop 112 configurations, e.g., double oven range appliances, standalone cooktop appliances, cooktop appliances without an oven, etc.

A cooking surface 114 of cooktop appliance 112 includes a plurality of heating elements 116. The heating elements 116 are generally positioned at, e.g., on or proximate to, the cooking surface 114. In certain exemplary embodiments, cooktop 112 may be an induction cooktop with induction heating elements mounted below cooking surface 114. For the embodiment depicted, the cooktop 112 includes five heating elements 116 spaced along cooking surface 114. However, in other embodiments, the cooktop appliance 112 may include any other suitable shape, configuration, and/or number of heating elements 116. Each of the heating elements 116 may be the same type of heating element 116, or cooktop appliance 112 may include a combination of different types of heating elements 116. For example, in various embodiments, the cooktop appliance 112 may include any other suitable type of heating element 116 in addition to the induction heating element, such as a resistive heating element or gas burners, etc.

As shown in FIG. 1, a cooking utensil 118, such as a pot, pan, or the like, may be placed on a heating element 116 to heat the cooking utensil 118 and cook or heat food items placed in cooking utensil 118. Range appliance 110 also includes a door 120 that permits access to a cooking chamber (not shown) of range appliance 110, e.g., for cooking or baking of food items therein. A control panel 122 having controls 124 permits a user to make selections for cooking of food items. Although shown on a backsplash or back panel 126 of range appliance 110, control panel 122 may be positioned in any suitable location. Controls 124 may include buttons, knobs, and the like, as well as combinations thereof, and/or controls 124 may be implemented on a remote user interface device such as a smartphone, tablet, etc. As an example, a user may manipulate one or more controls 124 to select a temperature and/or a heat or power output for each heating element 116. The selected temperature or heat output of heating element 16 affects the heat transferred to cooking utensil 118 placed on heating element 116. The control panel 122 may also include a display 128.

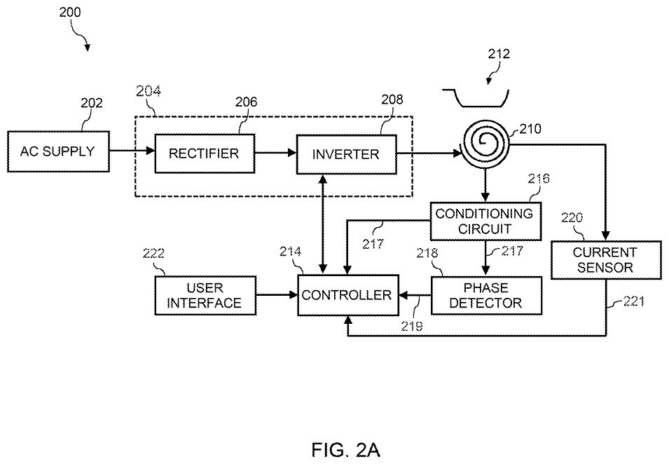

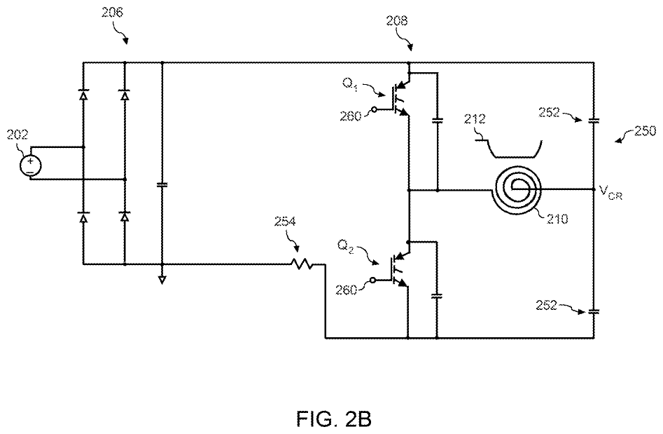

The cooktop appliance 100 includes a control system for controlling one or more of the plurality of heating elements 116. Specifically, the control system may include a controller operably coupled to the control panel 122 and the controls 124 and display 128 thereof. The controller may be operably coupled to each of the plurality of heating elements 116 for controlling a heating level each of the plurality of heating elements 116 in response to one or more user inputs received through the control panel 122 and controls 124. The controller may also provide output to the display 128, such as an indication of a selected power level, which heating element(s) 116 is or are activated, etc. Furthermore, as will be discussed in greater detail below, the controller may further be configured to control operation of an induction heating system 200 (FIGS. 2A-2B) of the cooktop appliance 100 based at least in part on one or more electrical characteristics and/or one or more operating parameters associated with the induction heating system 200.

FIGS. 2A-2B depict an example induction heating system 200 according to example embodiments of the present disclosure. More particularly, FIG. 2A depicts a block diagram of an example induction heating system 200, and FIG. 2B depicts a circuit schematic of the example induction heating system 200 depicted in FIG. 2A. The induction heating system 200 may be used in, for instance, the induction cooktop appliance 100 discussed above with reference to FIG. 1. It should be noted that the arrangement of the various components of the induction heating system 200 in FIGS. 2A-2B is for purposes of illustration and discussion. Those having ordinary skill in the art, using the disclosures provided herein, will appreciate that any suitable topology may be used without deviating from the scope of the present disclosure.

As will be discussed in greater detail below, in operation, the induction heating system 200 may be configured to detect a presence of a load (e.g., cookware 212) on an induction heating element (e.g., coil 210). The induction heating system 200 may be further configured to determine a total power output of an inverter 208 supplied to the induction heating element (e.g., coil 210). Hence, the induction heating system 200 may be configured to control the power supplied to the induction heating element (e.g., coil 210) at a power level selected by a user from a range of user-selectable power settings.

As shown in FIGS. 2A-2B, the induction heating system 200 generally includes an alternating current (AC) power supply 202. In some embodiments, the AC power supply 202 may provide conventional 60 Hz 120 VAC supplied by utility companies. Additionally and/or alternatively, the AC power supply 202 may provide conventional 208 VAC, 220 VAC, and/or 240 VAC supplied by utility companies.

It should be noted that an induction cooktop appliance according to the present disclosure (e.g., induction cooktop appliance 100) may include one or more induction heating systems 200. Those having ordinary skill in the art, using the disclosures provided herein, will appreciate that an induction cooktop appliance according to the present disclosure may have any suitable number of induction heating systems 200 without deviating from the scope of the present disclosure. For instance, in some embodiments, the induction cooktop appliance 100 may include a single induction heating system 200. Additionally and/or alternatively, the induction cooktop appliance 100 may include multiple induction heating systems 200. In such embodiments, each of the multiple induction heating systems 200 may be configured to communicate with each of the other induction heating systems 200 individually and/or with the induction cooktop appliance 100 as a whole.

The induction heating system 200 may further include a power supply circuit 204 coupled to the AC power supply 202. In this way, the AC power supply 202 and the power supply circuit 204 may be configured to supply a power signal to the induction heating system 200. In some embodiments, in addition to the components discussed below, the power supply circuit 204 may also include an electromagnetic interference (EMI) filter (not shown) coupled to the AC power supply 202. The power supply circuit 204 may further include a rectifier circuit 206 coupled to the AC power source 202. The rectifier circuit 206 may rectify the AC power signal provided by the AC power supply 202. The rectifier circuit 206 may further include a filter and power factor correction circuitry to filter the rectified voltage signal.

The power supply circuit 204 may further include an inverter 208. The rectifier circuit 206 may be coupled to the inverter 208. In this way, the rectifier circuit 206 may be configured to provide a rectified power signal to the inverter 208. Furthermore, the inverter 208 may be configured to supply an alternating current to an induction coil 210. Accordingly, the inverter 208 may also be termed a variable frequency inverter module. It should be understood that the induction heating system 200 is depicted as having a single coil 210 for purposes of illustration and discussion. The induction heating system 200 described herein may include any number of coils 210 without deviating from the scope of the present disclosure. For instance, in some embodiments, the inverter 208 may be configured to supply an alternating current to a plurality of induction coils 210.

The coil 210, when supplied by the inverter 208 with an alternating current, may inductively heat a load, such as cookware 212 or other objects placed on, over, or near the coil 210. It should be understood that use of the term “cookware” herein is merely exemplary, and that term will generally include any object of a suitable type that is capable of being heated by the coil 210. Furthermore, as used herein, the “power requirement” of the induction heating system 200 refers to a total power output required by the induction heating element (e.g., induction coil 210).

The frequency of the current supplied to the coil 210 by the inverter 208 and, hence, the output power of the coil 210 may be controlled by controller 214. It should be noted that the controller 214 is omitted from FIG. 2B for case of illustration. The controller 214 may control the switching frequency of the inverter 208 and one or more switching devices (e.g., switching devices Q1, Q2 (FIG. 2B)) of the inverter 208. The controller 214 may also be implemented as a microcontroller and/or gate driver to drive individual transistors or switching devices of the appliance 100 with pulse-width modulated signals. As shown, the controller 214 may be operably coupled to the power supply circuit 204. More particularly, the controller 214 may be operably coupled to the inverter 208 of the power supply circuit 204.

The controller 214 may also be operably coupled to conditioning circuitry (e.g., conditioning circuit 216). As will be discussed in greater detail below, the conditioning circuit 216 may be configured to generate (e.g., output) a derived voltage signal 217, which is a voltage signal representative of a current through the induction heating element (e.g., coil 210), based at least in part on a voltage across a resonant capacitor (e.g., resonant capacitor 252 (FIG. 2B)) of the induction heating system 200.

The controller 214 may also be operably coupled to phase detection circuitry (e.g., phase detector 218). In addition to the controller 214, the phase detector 218 may also be coupled to the conditioning circuit 216. As will be discussed in greater detail below, the phase detector 218 may be configured to output a voltage signal 219 representative of a phase of the current through the induction heating element (e.g., coil 210) based at least in part on the derived voltage signal 217 output by the conditioning circuit 216.

The controller 214 may be configured to determine one or more operating parameters of the induction heating system 200 based at least in part on one or more signals (e.g., derived voltage signal 217, voltage signal 219) generated by the conditioning circuit 216 and/or the phase detector 218. For instance, in some embodiments, the one or more operating parameters of the induction heating system 200 may include a current through the induction heating element (e.g., coil 210) provided by the power supply circuit 204 (e.g., inverter 208). Additionally and/or alternatively, the one or more operating parameters may also include a phase of the current through the induction heating element (e.g., coil 210). Additionally and/or alternatively, the one or more operating parameters may also include a total power output to the induction heating element (e.g., coil 210) by the inverter 208 of the power supply circuit 204. Additionally and/or alternatively, the one or more operating parameters may also include a phase difference between a voltage across a resonant tank 250 (FIG. 2B) of the induction heating system 200 and the current through the induction heating element (e.g., coil 210). In this way, the controller 214 may be configured to control operation of the induction heating system 200.

For instance, as noted above and as will be discussed in greater detail below, the controller 214 may be configured to determine whether a load (e.g., cookware 212) is present on the induction heating element (e.g., coil 210) based at least in part on the derived voltage signal 217 output by the conditioning circuit 216 and/or the voltage signal 219 output by the phase detector 218. The controller 214 may also be configured to determine a total power of the induction heating element (e.g., coil 210) based at least in part on the derived voltage signal 217 output by the conditioning circuit 216 and/or the voltage signal 219 output by the phase detector 218.

As will be discussed in greater detail below, in some embodiments, the induction heating system 200 may further include a current sensor 220 coupled thereto. The current sensor 220 may be configured to sense the current supplied to the induction heating element (e.g., coil 210) by the power supply circuit 204 (e.g., by inverter 208). As such, the current sensor 220 may be configured to output (e.g., provide)—to the controller 214—a current feedback signal 221 representative of a peak current provided to the induction heating element (e.g., coil 210) by the power supply circuit 204. More particularly, the current feedback signal 221 may be a signal that is representative of the current flowing through the induction heating element (e.g., coil 210) derived from one of a plurality of possible devices. For instance, the current sensor 220 may include a current transformer, a current shunt monitor (e.g., shunt resistor 254 (FIG. 2B)), a Hall effect sensor, or any other suitable current sensing device.

The controller 214 may also be coupled to a user interface 222. As shown, the user interface 222 may be operatively connected to the controller 214. The user interface 222 may allow a user to establish the power output of the induction heating system 200. More particularly, the user interface 222 may include one or more user input(s) (not shown) that allow the user to select a power setting from a plurality of user-selectable power settings. Furthermore, as will be discussed in greater detail below, the controller 214 may use the inputs from the user interface 222, the derived voltage signal 217 from the conditioning circuit 216, the voltage signal 219 from the phase detector 218, and the current feedback signal 221 from the current sensor 220 to control energization of the induction heating element (e.g., coil 210).

In some embodiments, the controller 214 may be operative to control the frequency of the power signal generated by the inverter 208 to operate the induction heating element (e.g., coil 210) at the power level corresponding to the setting selected by the user via the user interface 222. The controller 214 may monitor and process one or more signal generated by various components of the induction heating system 200 (e.g., derived voltage signal 217, voltage signal 219, current feedback signal 221, etc.) to determine the presence of the load (e.g., cookware 212) on the induction heating element (e.g., coil 210), the size and/or type of the load if present, and the resonant frequency of the power supply circuit 204 with the load (e.g., cookware 212) present. Based on the size and/or type of the load (e.g., cookware 212), or lack thereof, the controller 214 may be configured to control power to the induction heating element (e.g., coil 210), which may, in some embodiments, include turning the power on and/or off.

The derived voltage signal 217, the voltage signal 219, and the current feedback signal 221 may be sampled repetitively during each full switching cycle. The collection of sampled values of the derived voltage signal 217, the voltage signal 219, and the current feedback signal 221 over a switching cycle may include a current signature, which is captured and analyzed by the controller 214 to determine the one or more operating parameters, such as a phase and current through the induction heating element (e.g., coil 210).

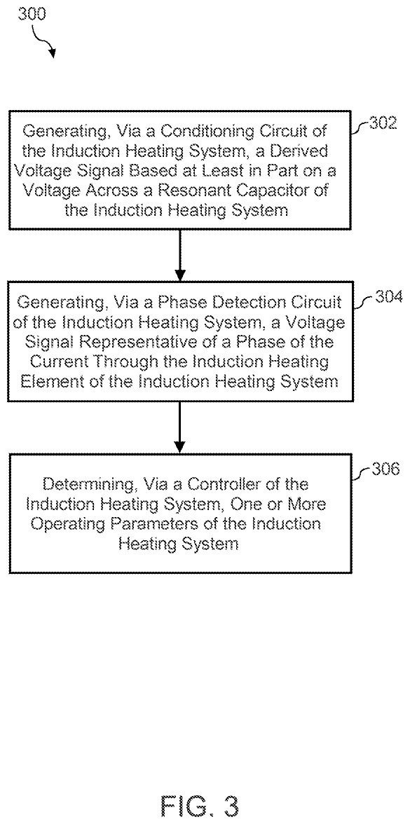

As discussed below with reference to FIGS. 3-8, the controller 214 may include one or more processors (not shown) configured to perform operations to determine the one or more operating parameters of the induction heating system 200 and, hence, control the induction heating system 200. More particularly, in some embodiments, the controller 214 may receive the derived voltage signal 217 from the conditioning circuit 216, as well as the voltage signal 219 from the phase detector 218, and may determine the one or more operating parameters of the induction heating system 200 based at least in part on the derived voltage signal 217 and the voltage signal 219. Additionally and/or alternatively, the controller 214 may receive the voltage signal 219 from the phase detector 218, as well as the current feedback signal 221 from the current sensor 220, and may determine the one or more operating parameters of the induction heating system 200 based at least in part on the voltage signal 219 and the current feedback signal 221. In fact, as will be discussed in greater detail below, the controller 214 may be configured to determine the one or more operating parameters of the induction heating system 200 based on any combination of the signals discussed herein without deviating from the scope of the present disclosure.

FIG. 3 depicts a flow diagram of an example method 300 for operating an appliance, such as an induction cooktop appliance, according to example embodiments of the present disclosure. More particularly, method 300 can be implemented in an induction heating system (e.g., induction heating system 200) of any suitable cooktop appliance (e.g., cooktop appliance 100). FIG. 3 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. Furthermore, various steps (not illustrated) can be performed without deviating from the scope of the present disclosure. Additionally, method 300 is generally discussed with reference to the cooktop appliance 100 described above with reference to FIG. 1 and the induction heating system 200 described above with reference to FIGS. 2A-2B. However, it should be understood that aspects of the present method 300 can find application with any suitable cooktop appliance (e.g., induction cooktop appliance, range appliance, etc.) and any suitable induction heating system.

The method 300 may include, at (302), generating, via a conditioning circuit of the induction heating system, a derived voltage signal based at least in part on a voltage across a resonant capacitor of the induction heating system. More particularly, a conditioning circuit (e.g., conditioning circuit 216) may generate a derived voltage signal (e.g., derived voltage signal 217) based on a voltage signal representative of a voltage across a resonant capacitor (e.g., resonant capacitor 252) of the induction heating system 200. As noted above, the derived voltage signal 217 is representative of a current through an induction heating element (e.g., coil 210) of the induction heating system 200.

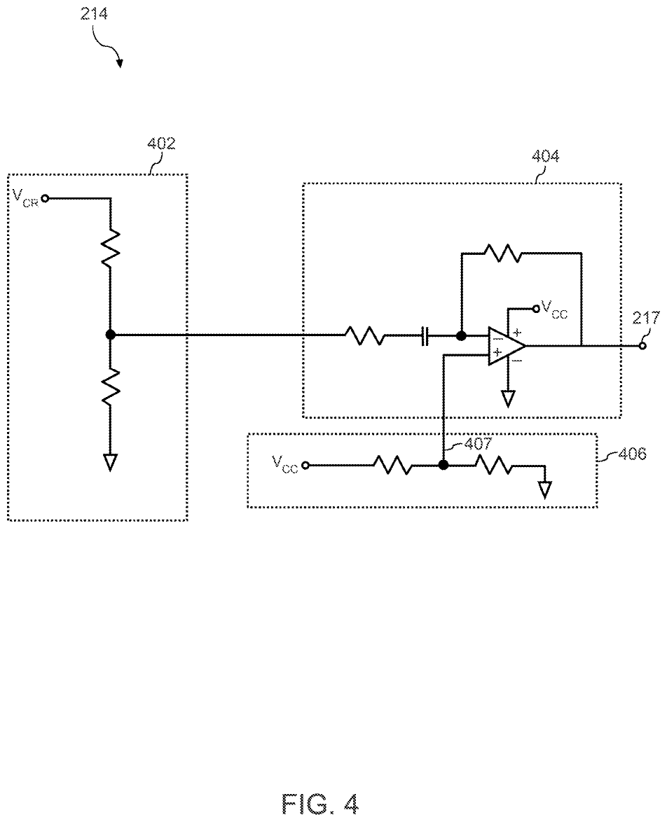

As an illustrative example, FIG. 4 depicts a circuit schematic of an example conditioning circuit 216 of the induction heating system 200 according to example embodiments of the present disclosure. It should be noted that the arrangement of the various components of the conditioning circuit 216 in FIG. 4 is for purposes of illustration and discussion. Those having ordinary skill in the art, using the disclosures provided herein, will appreciate that any suitable topology may be used without deviating from the scope of the present disclosure.

As noted above, the conditioning circuit 216 may be configured to output a derived voltage signal 217 based at least in part on a voltage across a resonant capacitor, such as resonant capacitor 252 (FIG. 2B) of the induction heating system 200. Furthermore, as shown, the conditioning circuit 216 may include a resistor divider 402, a differentiator circuit 404, and an offset circuit 406.

The resistor divider 402 may be configured to receive a signal indicative of the voltage across the resonant capacitor 252 (FIG. 2), and an output of the resistor divider 402 may be coupled to an input of the differentiator circuit 404. The differentiator circuit 404 may receive the signal output by the resistor divider 402 and, in response, may take the derivative of that signal output by the resistor divider 402. The conditioning circuit 216 may further include an offset circuit 406 coupled to the differentiator circuit 404. The offset circuit 406 may add a direct-current (DC) voltage offset (e.g., offset reference voltage 407) to the signal output by the differentiator circuit 404. In this way, the conditioning circuit 216 is configured to use the resistor divider 402, take a derivative of the signal output from the resistor divider 402 with the differentiator circuit 404, and add a DC offset with the offset circuit 406 to generate a derived voltage signal 217.

As noted above, the derived voltage signal 217 is a voltage signal representative of the current through the induction heating element (e.g., coil 210) of the induction heating system 200. Furthermore, as will be discussed in greater detail below, the conditioning circuit 216 may provide the derived voltage signal 217 to various other components of the induction heating system 200 for further signal processing and parameter determination.

Returning to FIG. 3, the method 300 may include, at (304), generating, via a phase detection circuit of the induction heating system, a voltage signal representative of the phase of the current through the induction heating element of the induction heating system. More particularly, a phase detection circuit (e.g., phase detector 218) may receive the derived voltage signal 217 generated by the conditioning circuit 216 at (302) and, in response, may generate a voltage signal (e.g., voltage signal 219) based at least in part on the derived voltage signal 217.

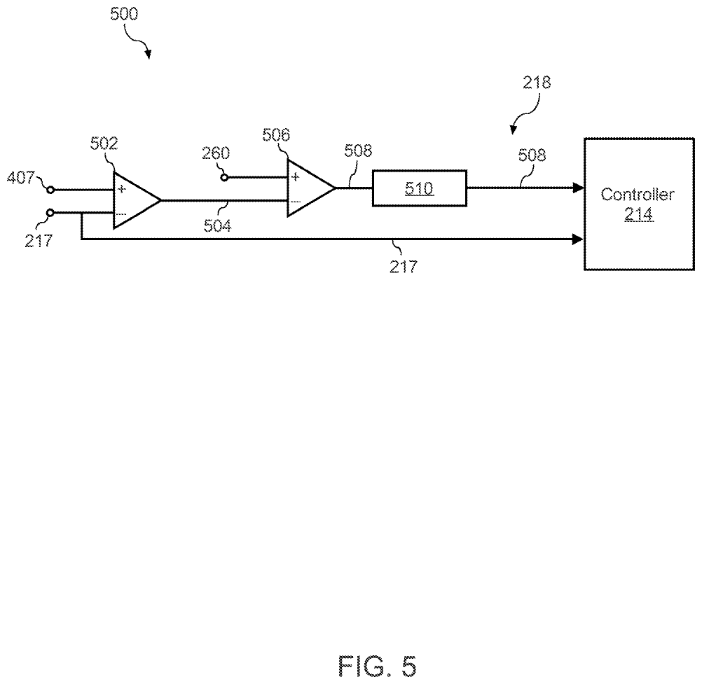

As an illustrative example, FIGS. 5-8 depict circuit schematics of various configurations of an example phase detector 218 of the induction heating system 200 according to example embodiments of the present disclosure. It should be noted that, as used herein, “phase detection circuit” and “phase detector” may be used interchangeably and both refer to a circuit configured to output a voltage signal (e.g., voltage signal 219) representative of a phase of the current through the induction heating element (e.g., coil 210). It should be noted that the example configurations of the phase detectors 218 depicted in FIGS. 5-8 are for purposes of illustration and discussion. Those having ordinary skill in the art, using the disclosures provided herein, will appreciate that any suitable topology may be used without deviating from the scope of the present disclosure.

Referring now to FIG. 5, an example configuration 500 of the phase detector 218 of the induction heating system 200 is depicted. As shown, the phase detector 218 may include one or more comparators, such as comparator 502 and comparator 506. For case of discussion, comparator 502 is hereinafter referred to as “first comparator 502,” and comparator 506 is hereinafter referred to as “second comparator 506.”

As shown, the first comparator 502 may be configured to receive the derived voltage signal 217 from the conditioning circuit 216 (FIGS. 2A, 4). The first comparator 502 may compare the derived voltage signal 217 to an offset reference voltage 407 which, as noted above, is representative of the DC voltage offset added by the offset circuit 406 (FIG. 4) of the conditioning circuit 216. Put differently, the first comparator 502 may output a first voltage pulse signal 504 based at least in part on the comparison of the derived voltage signal 217 to the offset reference voltage 407. As such, the first comparator 502 may output a positive pulse (e.g., first voltage pulse signal 504) when the derived voltage signal 217 is less than the offset reference voltage 407. The first comparator 502 may then provide the first voltage pulse signal 504 to the second comparator 506.

The second comparator 506 may be coupled to an output of the first comparator 502, so that the second comparator 506 may receive the first voltage pulse signal 504 from the first comparator 502. The second comparator 506 may compare the first voltage pulse signal 504 generated by the first comparator 502 to a pulse-width modulated (PWM) signal 260 which, as noted above, is representative of a PWM voltage signal fed to the power supply circuit 204 (FIGS. 2A-2B) (e.g., to switching device Q1 and/or switching device Q2). The PWM signal 260 may be a close representation of the voltage across the resonant tank 250 (FIG. 2B). Put differently, the second comparator 506 may output a second voltage pulse signal 508 based at least in part on the comparison of the first voltage pulse signal 504 to the PWM signal 260. In some embodiments, the second comparator 506 may then provide the second voltage pulse signal 508 to a filter 510 (e.g., a low-pass filter (LPF)) before ultimately providing the second voltage pulse signal 508 to the controller 214. In other embodiments, the second comparator 506 may provide the second voltage pulse signal 508 directly to the controller 214.

As noted above, the controller 214 may be configured to determine one or more operating parameters of the induction heating system 200. For instance, in the example configuration 500 depicted in FIG. 5, the controller 214 may receive the second voltage pulse signal 508 from the phase detector 218. Furthermore, as shown, the controller 214 may also receive the derived voltage signal 217 from the conditioning circuit 216 (FIG. 4). In this way, the controller 214 may determine the one or more operating parameters of the induction heating system 200, such as the phase of the current through the induction heating element (e.g., coil 210), based at least in part on the derived voltage signal 217 and the second voltage pulse signal 508.

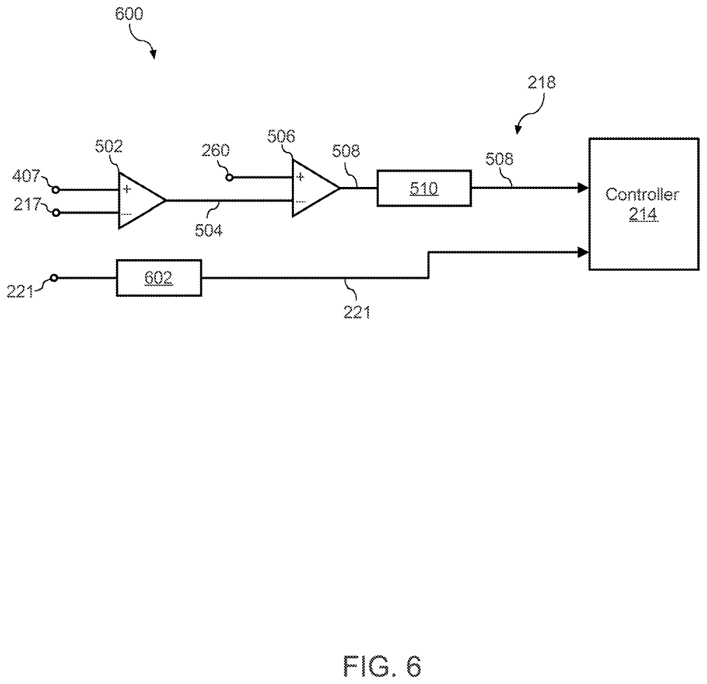

Referring now to FIG. 6, another example configuration 600 of the phase detector 218 of the induction heating system 200 is depicted. The phase detector 218 (having configuration 600) depicted in FIG. 6 is similar to the phase detector 218 (having configuration 500) discussed above with reference to FIG. 5. For instance, the phase detector 218 may include the first comparator 502 and the second comparator 506. The first comparator 502 and the second comparator 506 may output a first voltage pulse signal 504 and a second voltage pulse signal 508, respectively, in the same manner as set forth above.

However, in contrast to the phase detector 218 (having configuration 500), the phase detector 218 (having configuration 600) does not independently provide the derived voltage signal 217 to the controller 214. Instead, a current sensor 220 (FIG. 2A) provides a current feedback signal 221 to the controller 214. For instance, as noted above, the induction heating system 200 may include a current sensor 220, such as a shunt resistor 254 (FIG. 2B), configured to measure the current through the induction heating element (e.g., coil 210) of the induction heating system 200, and the current sensor 220 may then provide a current feedback signal 221 representative of the current through the induction heating element (e.g., coil 210) to the controller 214. By using the current feedback signal 221 instead of the derived voltage signal 217 as the current reference signal, design tradeoffs associated with the tolerance associated with the resonant capacitor 250 (FIG. 2B) may be reduced. It should be noted that any suitable current sensor may be used without deviating from the scope of the present disclosure.

In some embodiments, the current feedback signal 221 may first be conditioned prior to being provided to the controller 214. More particularly, in some embodiments, the current feedback signal 221 may be provided to a second conditioning circuit 602, where the current feedback signal 221 is, e.g., filtered, amplified, offset, etc. It should be noted that the current feedback signal 221 may be conditioned in any suitable manner without deviating from the scope of the present disclosure.

As such, to determine the one or more operating parameters of the induction heating system 200, the controller 214 may receive the second voltage pulse signal 508 from the phase detector 218 in the same manner as set forth above with reference to FIG. 5. Furthermore, rather than receiving the derived voltage signal 217, the controller 214 may also receive the current feedback signal 221 from the current sensor 220. In this way, the controller 214 may determine the one or more operating parameters of the induction heating system 200, such as the phase of the current through the induction heating element (e.g., coil 210), based at least in part on the second voltage pulse signal 508 and the current feedback signal 221.

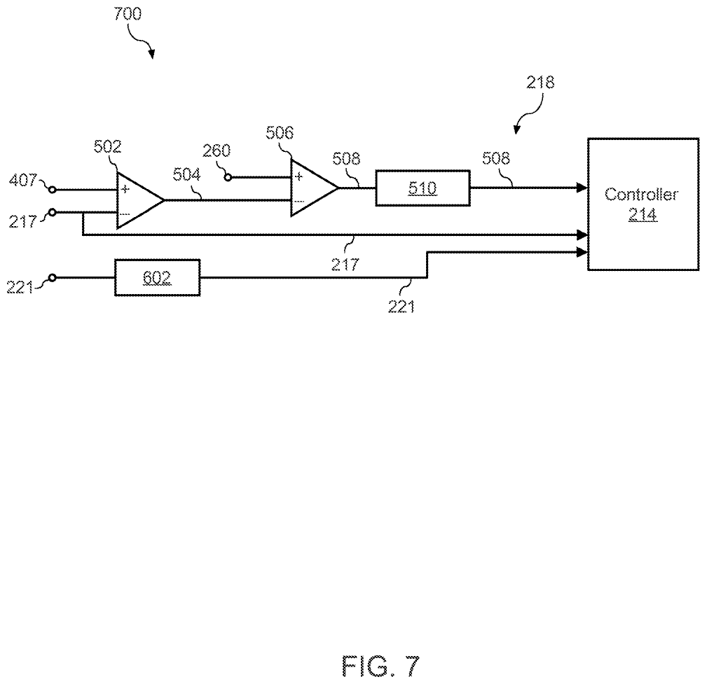

Referring now to FIG. 7, another example configuration 700 of the phase detector 218 of the induction heating system 200 is depicted. The phase detector 218 (having configuration 700) depicted in FIG. 7 is a combination of the phase detector 218 (having configuration 500) and the phase detector 218 (having configuration 600) discussed above with reference to FIG. 5 and FIG. 6, respectively. For instance, the phase detector 218 may include the first comparator 502 and the second comparator 506. The first comparator 502 and the second comparator 506 may output a first voltage pulse signal 504 and a second voltage pulse signal 508, respectively, in the same manner as set forth above.

The second voltage pulse signal 508 may be provided to the controller 214 by the second comparator 506 in the same manner as set forth above. Furthermore, like the phase detector 218 of FIG. 5, the derived voltage signal 217 may also be provided to the controller 214. Even further, like the phase detector 218 of FIG. 6, the current feedback signal 221 may also be provided to the controller 214. As such, to determine the one or more operating parameters of the induction heating system 200, the controller 214 may receive derived voltage signal 217 from the conditioning circuit 216 and the second voltage pulse signal 508 from the phase detector 218 in the same manner as set forth above with reference to FIG. 5. The controller 214 may also receive the current feedback signal 221 from the current sensor 220 in the same manner as set forth above with reference to FIG. 6. In this way, the controller 214 may determine the one or more operating parameters of the induction heating system 200, such as the phase of the current through the induction heating element (e.g., coil 210), based at least in part on the derived voltage signal 217, the second voltage pulse signal 508, and the current feedback signal 221.

Furthermore, as noted above, the current feedback signal 221 is representative of a peak current measured by the current sensor 220. The peak current measured by the current sensor 220 may represent the peak current through the induction heating element (e.g., coil 210) multiplied by a fixed scalar, because the current through the current sensor 220 (e.g., shunt resistor 254) is approximately half of the current through the induction heating element (e.g., coil 210). As such, based on this relationship between the current through the current sensor 220 (represented by current feedback signal 221) and the current through the induction heating element (e.g., coil 210), the controller 214 may be further configured to adjust the derived voltage signal 217 to compensate for the tolerance associated with the resonant capacitor 252 (FIG. 2B) of the induction heating system 200.

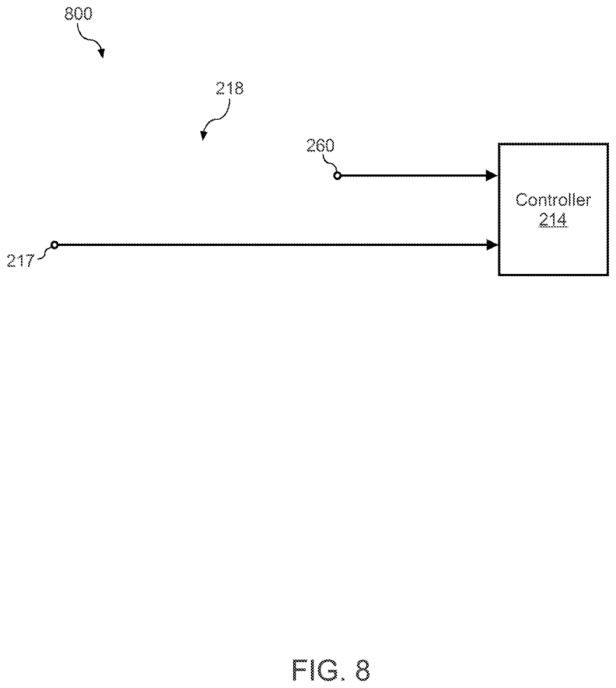

In some embodiments, the phase detection circuitry may be internal to the controller 214. For instance, referring now to FIG. 8, another example configuration 800 of the phase detector 218 of the induction heating system 200 is depicted. In contrast to the phase detectors 218 discussed above with reference to FIGS. 5-7, in some embodiments, the derived voltage signal 217 may be fed directly to the controller 214, rather than to a comparator.

For instance, as shown, the derived voltage signal 217 may be output from the conditioning circuit 216, and the controller 214 may receive the derived voltage signal 217 from the conditioning circuit 216. Furthermore, the controller 214 may also receive the PWM signal 260 which, as noted above, is representative of a PWM voltage signal fed to the power supply circuit 204 (FIGS. 2A-2B). The controller 214 may initiate a timer operation (e.g., start a timer) when the PWM signal 260 fed back to the controller 214 is positive. The controller 214 may halt the timer operation (e.g., stop the timer) when the derived voltage signal 217 is greater than the offset reference voltage 407 which, as noted above, is representative of the DC voltage offset added by the offset circuit 406 (FIG. 4) of the conditioning circuit 216. The result of the timer operation (hereinafter referred to as the “total time”) may be used by the controller 214, in conjunction with an operating frequency of the induction heating system 200, to calculate the one or more operating parameters of the induction heating system 200, such as the phase of the current through the induction heating element (e.g., coil 210).

Put differently, to determine the phase of the current through the induction heating element (e.g., coil 210), the controller 214 may receive a positive PWM signal (e.g., PWM signal 260). The controller 214 may then initiate a timer operation in response to receiving the positive PWM signal. Next, the controller 214 may determine whether the derived voltage signal 217 is greater than the offset reference voltage 407, and, in response to determining that the derived voltage signal 217 is greater than the offset reference voltage 407, the controller 214 may halt the timer operation. As such, the controller 214 may determine the phase of the current through the induction heating element (e.g., coil 210) based at least in part on the operating frequency associated with the induction heating system 200 and the total time associated with the timer operation.

As such, to determine the one or more operating parameters of the induction heating system 200, the controller 214 may receive derived voltage signal 217 from the conditioning circuit 216 and the second voltage pulse signal 508 from the phase detector 218 in the same manner as set forth above with reference to FIG. 5. The controller 214 may also receive the current feedback signal 221 from the current sensor 220 in the same manner as set forth above with reference to FIG. 6. In this way, the controller 214 may determine the one or more operating parameters of the induction heating system 200, such as the phase of the current through the induction heating element (e.g., coil 210), based at least in part on the derived voltage signal 217, the second voltage pulse signal 508, and the current feedback signal 221.

Returning to FIG. 3, the method 300 may include, at (306), determining, via a controller of the induction heating system, one or more operating parameters of the induction heating system based at least in part on the derived voltage signal. More particularly, the controller 214 may be configured to determine one or more operating parameters of the induction heating system 200 based at least in part on the derived voltage signal 217 generated by the conditioning circuit 216. For instance, as noted above, the one or more operating parameters of the induction heating system 200 may include the current through the induction heating element provided by the power supply circuit 204, the phase of the current through the induction heating element, the total power output to the induction heating element by the inverter 208 of the power supply circuit 204, and/or the phase difference between the voltage across the resonant tank 250 and the current through the induction heating element.

Based at least in part on these operating parameters, the controller 214 may be configured to determine whether a load (e.g., cookware 212) is present on the induction heating element (e.g., coil 210). Furthermore, the controller 214 may also be configured to determine the total power output at the inverter 208 based at least in part on these operating parameters. Even further, the controller 214 may also be configured to determine a size and/or type of load (e.g., cookware 212) based on these operating parameters when applicable.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. An induction heating system, comprising:
an induction heating element operable to inductively heat a load with a magnetic field;
a power supply circuit coupled to an alternating current (AC) power supply configured to supply a power signal to the induction heating system, the power supply circuit comprising an inverter;
a conditioning circuit configured to output a derived voltage signal based at least in part on a voltage across a resonant capacitor of the induction heating system; and
a controller operably coupled to the conditioning circuit and the power supply circuit, the controller configured to determine one or more operating parameters of the induction heating system based at least in part on the derived voltage signal generated by the conditioning circuit.

2. The induction heating system of claim 1, wherein the one or more operating parameters comprise at least one of a current through the induction heating element, a total power output to the induction heating element by the inverter of the power supply circuit, a phase of the current through the induction heating element, or a phase difference between a voltage across a resonant tank of the induction heating system and the current through the induction heating element.

3. The induction heating system of claim 1, wherein the conditioning circuit comprises:
a resistor divider configured to receive a signal indicative of the voltage across the resonant capacitor of the induction heating system;
a differentiator circuit coupled to the resistor divider, the differentiator circuit configured to determine a derivative of a signal output by the resistor divider; and
an offset circuit coupled to the differentiator circuit, the offset circuit configured to add a direct-current (DC) offset to a signal output by the differentiator circuit.

4. The induction heating system of claim 1, wherein the derived voltage signal is a voltage signal representative of a current through the induction heating element of the induction heating system.

5. The induction heating system of claim 4, further comprising:
a phase detection circuit coupled to the conditioning circuit and to the controller, the phase detection circuit configured to output a voltage signal representative of a phase of the current through the induction heating element based at least in part on the derived voltage signal output by the conditioning circuit.

6. The induction heating system of claim 5, wherein the phase detection circuit comprises:
a first comparator configured to output a first voltage pulse signal based at least in part on a comparison of the derived voltage signal to an offset reference voltage representative of a DC offset added by the conditioning circuit; and
a second comparator coupled to an output of the first comparator, the second comparator configured to output a second voltage pulse signal based at least in part on a comparison of the first voltage pulse signal to a pulse-width modulated (PWM) signal representative of a PWM voltage signal fed to the power supply circuit.

7. The induction heating system of claim 6, wherein the controller is configured to determine the one or more operating parameters by performing operations, the operations comprising:
receiving the derived voltage signal from the conditioning circuit;
receiving the second voltage pulse signal from the phase detection circuit; and
determining the one or more operating parameters of the induction heating system based at least in part on the derived voltage signal and the second voltage pulse signal.

8. The induction heating system of claim 6, further comprising:
a current sensor coupled to the induction heating system, the current sensor configured to output a current feedback signal representative of a peak current provided to the induction heating element, wherein the current sensor is a shunt resistor, a current transformer, or a Hall effect sensor.

9. The induction heating system of claim 8, wherein the controller is configured to determine the one or more operating parameters of the induction heating system by performing operations, the operations comprising:
receiving the second voltage pulse signal from the phase detection circuit;
receiving the current feedback signal from the current sensor; and
determining the one or more operating parameters of the induction heating system based at least in part on the second voltage pulse signal and the current feedback signal.

10. The induction heating system of claim 9, wherein the operations further comprise:
receiving the derived voltage signal from the conditioning circuit;
wherein the controller is configured to determine the one or more operating parameters of the induction heating system based at least in part on the derived voltage signal, the second voltage pulse signal, and the current feedback signal.

11. The induction heating system of claim 10, wherein the controller is configured to adjust the derived voltage signal based at least in part on the current feedback signal to compensate for a tolerance associated with the resonant capacitor of the induction heating system.

12. The induction heating system of claim 4, wherein the controller is configured to determine the one or more operating parameters of the induction heating system by performing operations, the operations comprising:
receiving the derived voltage signal from the conditioning circuit;
receiving a pulse-width modulated (PWM) signal representative of a PWM voltage signal fed to the power supply circuit; and
determining a phase of the current through the induction heating element based at least in part on the derived voltage signal and the PWM signal.

13. The induction heating system of claim 12, wherein, to determine the phase of the current through the induction heating element, the operations further include:
receiving a positive PWM signal;
initiating a timer operation in response to receiving the positive PWM signal;
determining whether the derived voltage signal is greater than an offset reference voltage;
halting the timer operation in response to determining the derived voltage signal is greater than the offset reference voltage; and
determining the phase of the current through the induction heating element based at least in part on an operating frequency associated with the induction heating system and a total time associated with the timer operation.

14. The induction heating system of claim 1, wherein, based at least in part on the derived voltage signal, the controller is configured to:
determine whether a load is present on the induction heating element, and
determine a total power of the induction heating element.

15. A method for operating an appliance comprising an induction heating system, the method comprising:
generating, via a conditioning circuit of the induction heating system, a derived voltage signal based at least in part on a voltage across a resonant capacitor of the induction heating system; and
determining, via a controller of the induction heating system, one or more operating parameters of the induction heating system based at least in part on the derived voltage signal.

16. The method of claim 15, wherein the derived voltage signal is representative of a current through an induction heating element of the induction heating system.

17. The method of claim 16, further comprising:
receiving, at a phase detection circuit of the induction heating system, the derived voltage signal from the conditioning circuit; and
generating, via the phase detection circuit, a voltage signal representative of a phase of the current through the induction heating element.

18. The method of claim 17, further comprising:
determining, via the controller, whether a load is present on the induction heating element based at least in part on the one or more operating parameters.

19. The method of claim 17, wherein the induction heating system comprises an inverter configured to supply a power signal to the induction heating system, the method further comprising:
determining, via the controller, a total power output of the inverter based at least in part on the one or more operating parameters.

20. An appliance, comprising:
a cooktop;
a user interface comprising a user input; and
an induction heating system comprising:
an induction heating element operable to inductively heat a load with a magnetic field;
a power supply circuit coupled to an alternating current (AC) power supply configured to supply a power signal to the induction heating system, the power supply circuit comprising an inverter;
a conditioning circuit configured to output a derived voltage signal based at least in part on a voltage across a resonant capacitor of the induction heating system; and
a controller operably coupled to the conditioning circuit and the power supply circuit, the controller configured to determine one or more operating parameters of the induction heating system based at least in part on the derived voltage signal generated by the conditioning circuit.
